(19) United States
(12) Patent Application Publication
(10) Pub. No.: US 2019/0131114 A1
(43) Pub. Date: May 2, 2019

(54) FOCUS RING, PLASMA APPARATUS AND VOLTAGE-ADJUSTING METHOD USING THE SAME

(71) Applicant: INDUSTRIAL TECHNOLOGY RESEARCH INSTITUTE, HSIN-CHU (TW)

(72) Inventors: CHIA-HAO CHANG, HSINCHU COUNTY (TW); KUAN-YU LIN, TAOYUAN CITY (TW); CHIH-HUNG LIU, TAICHUNG CITY (TW); JHIH-REN LIN, NEW TAIPEI CITY (TW); CHIA-MING CHEN, HSINCHU COUNTY (TW); KUAN-CHOU CHEN, HSINCHU CITY (TW)

(21) Appl. No.: 15/835,660

(22) Filed: Dec. 8, 2017

(30) Foreign Application Priority Data
Oct. 26, 2017 (TW) 106136972

(51) Int. Cl. H01J 37/32; H01L 21/311; G03F 7/09

(52) U.S. Cl. CPC H01J 37/32642; H01J 37/32091; G03F 7/094; H01J 37/32504; H01L 21/31116; H01J 37/3266

(57) ABSTRACT

A focus ring includes a main body, a plurality of electrodes and a plurality of power cables. The main body, made of a dielectric material, is formed as a frame structure to surround a base. The plurality of electrodes, made of metallic materials, are located inside the main body by surrounding the base, and the neighboring electrodes are separated by an interval. Each of the power cables is connected electrically with a voltage source, a control unit and at least one electrode. The voltage source inputs individual voltages to the plurality of electrodes via the plurality of respective power cables. The control unit controls the plurality of electrodes to have correspondingly a plurality of voltages.

### CROSS REFERENCE TO RELATED APPLICATION

This application claims the benefits of Taiwan application Serial No. 106136972, filed Oct. 26, 2017, the disclosures of which are incorporated by references herein in its entirety.

### TECHNICAL FIELD

The present disclosure relates in general to a focus ring, a plasma apparatus and a voltage-adjusting method using the focus ring, and more particularly to the focus ring, the plasma apparatus and the voltage-adjusting method using the focus ring.

### BACKGROUND

Referring to FIG. 6, a conventional plasma apparatus 90 is schematically shown. In a typical plasma manufacturing process (for example, etching or film-coating process) for semiconductor components, an electrostatic chuck (ESC) 91 is usually applied to suck and fix a wafer 92, and a radio-frequency (RF) voltage power is applied to a lower electrode 93 of the electrostatic chuck 91 so as to attract ions to bombard a surface of the wafer 92 and thus to achieve the expected process goal. At the same time, heat resulted from the ion bombarding is removed by backside He cooling (backside He cooling), such that a surface temperature of the wafer 92 can be maintained for fulfilling successfully the production.

To prevent the electrostatic chuck 91 from being directly exposed to the plasma (i.e., the ion bombarding flow) so as to result in unexpected damages (for example, by corrosive gases and high-energy ion bombardment), an area of the electrostatic chuck 91 would be designed purposely to be smaller than that of the wafer 92. Therefore, electrodes arranged on the electrostatic chuck 91 would be impossible to cover an edge of the wafer 92 and areas outer to the edge. As a result, a distribution of voltage strength of the electric field at the edge would present a discontinuous phenomenon, from which the ion bombarding energy and direction at this area would be different to those at the other areas. Thereupon, a resulted etching production, for example, would be nonuniform. Such a phenomenon is called as an edge effect. This edge effect would form a useless area at the edge of the wafer 92, and inevitably leads to reduction in yield and production. In order to minimize the useless area at the edge of the wafer 92, an annular focus ring 94 is introduced to encircle the wafer 92 so as hopefully to adjust the distribution of electric field around the wafer 92.

Nevertheless, in a practical plasma chamber, besides the edge effect, the structure of the chamber also plays an important part in distorting the electric field. For example, since a typical plasma chamber is generally furnished with an entrance for the wafer 92 to move in/out, the plasma would be led non-uniformly toward the entrance of the plasma chamber. Referring now to FIG. 7A to FIG. 7C, density distributions of plasma for three different horizontal cross sections of the plasma chamber at three different heights are shown, respectively; in which the height of the cross section for FIG. 7A is about 10.2 cm, that for FIG. 7B is about 5.4 cm, and that for FIG. 7C is about 3.4 cm. In these plots, different color depths are applied to illustrate changes in the density of plasma. As shown in each of FIG. 7B and FIG. 7C, since the corresponding cross sections include the entrance of the plasma chamber, thus obvious plasma distortion is shown in an additional sector area. Thus, the distribution of the plasma inside the chamber would become axially asymmetric, from which non-uniform distribution of electric field around the wafer 92 would be induced.

Ideally, from a 10×10 mm semiconductor wafer with a 200 mm thickness, 284 chips can be produced. However, due to the non-uniform distribution of electric field, it can be foreseen that about 12-28 chips will be lost at the edge of the wafer. Apparently, the production amount is sacrificed. In the art, various changes in producing the focus ring have been proposed to improve the aforesaid situation at the edge of the wafer. These efforts mainly for varying the distribution of electric field include changes in materials, dielectricity or impedance, or a change in the height of focus ring. However, most of the aforesaid efforts are featured in complicated structuring, difficulty in adjusting and poor precision. Importantly, the aforesaid efforts involve changes to the entire focus ring, and are impossible to perform localized adjustment upon some distinct areas in the electric field around the wafer.

In the foregoing description, though the concerned shortcomings of the plasma apparatus is elucidated by having the wafer product as a typical example, yet it shall be understood that these shortcomings do prevail in most of the plasma apparatuses, including the plasma apparatus for etching and/or sputtering substrates.

### SUMMARY

In this disclosure, an embodiment of a focus ring includes a main body, a plurality of electrodes and a plurality of power cables. The main body, made of a dielectric material, is formed as a frame structure to surround a base. The plurality of electrodes, made of metallic materials, are located inside the main body by surrounding the base, and the neighboring electrodes are separated by an interval. Each of the power cables is connected electrically with a voltage source, a control unit and at least one electrode. The voltage source inputs individual voltages to the plurality of electrodes via the plurality of respective power cables. The control unit controls the plurality of electrodes to have correspondingly a plurality of voltages.

In another embodiment of this disclosure, a plasma apparatus includes a processing chamber, a base, a lower electrode, an upper electrode and a focus ring. The base, located inside the processing chamber, is to carry thereon a workpiece. The lower electrode is located inside the base. The upper electrode, located inside the processing chamber at a place above the base, forms an electrode pair with the lower electrode inside the base. The focus ring further includes a main body, a plurality of electrodes and a plurality of power cables. The main body, made of a dielectric material, is formed as a frame structure to surround the base. The plurality of electrodes, made of metallic materials, are located inside the main body by surrounding the base, and the neighboring electrodes are separated by an interval. Each of the power cables is connected electrically with a voltage source, a control unit and at least one electrode. The voltage source inputs individual voltages to the plurality of electrodes via the plurality of respective power cables. The control unit controls the plurality of electrodes to have correspondingly a plurality of voltages.

In a further embodiment of this disclosure, a voltage-adjusting method includes the steps of:

disposing a focus ring into a plasma apparatus, the focus ring including a main body made of a dielectric material, a plurality of electrodes made of metallic materials and a plurality of power cables, the main body being formed as a frame structure to surround a base, the neighboring ones of the plurality of electrodes being separated by an interval, the plurality of electrodes being located inside the main body and surrounding the base, each of the power cables being connected with a voltage source, a control unit and at least one of the plurality of electrodes, the voltage source inputting individual voltages into the plurality of electrodes, respectively, correspondingly via the plurality of power cables;

applying the control unit to sense a state of electric field inside the plasma apparatus so as thereby to determine an adjustment value; and

having the control unit to control the individual voltages inputted respectively to the plurality of electrodes, so that the plurality of electrodes have a plurality of voltages respectively to allow a surface of the focus ring to present different distributions of voltage strengths.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 shows schematically and cross-sectionally a focus ring of this disclosure that is disposed to sleeve a base;

FIG. 2 is a top view of an exemplary example of FIG. 1;

FIG. 3 is a top view of another exemplary example of FIG. 1;

FIG. 4 is a schematic view of a plasma apparatus in accordance with this disclosure;

FIG. 5 is a flowchart of a voltage-adjusting method in accordance with this disclosure;

FIG. 6 is a schematic view of part of a conventional plasma apparatus;

FIG. 7A is a plot of a density distribution of plasma for a horizontal cross section of a typical plasma chamber at a height of about 10.2 cm;

FIG. 7B is a plot of a density distribution of plasma for a horizontal cross section of the typical plasma chamber at a height of about 5.4 cm; and

FIG. 7C is a plot of a density distribution of plasma for a horizontal cross section of the typical plasma chamber at a height of about 3.4 cm.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

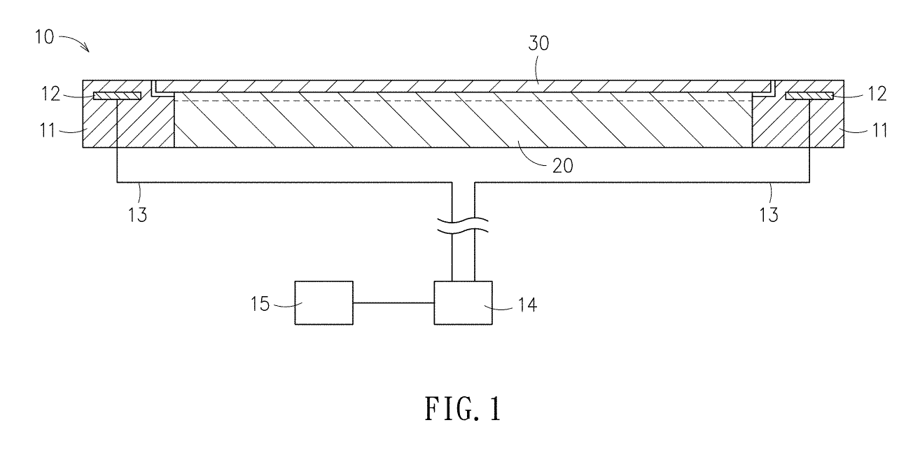

Referring now to FIG. 1, a focus ring 10 of this disclosure includes a main body 11, a plurality of electrodes 12 and a plurality of power cables 13.

The main body 11, made of a dielectric material such as a ceramics, is formed as a frame structure to encircle a base 20. The base 20 is used to carry thereon a workpiece 30 by, but not limited to, electrostatic adhesion.

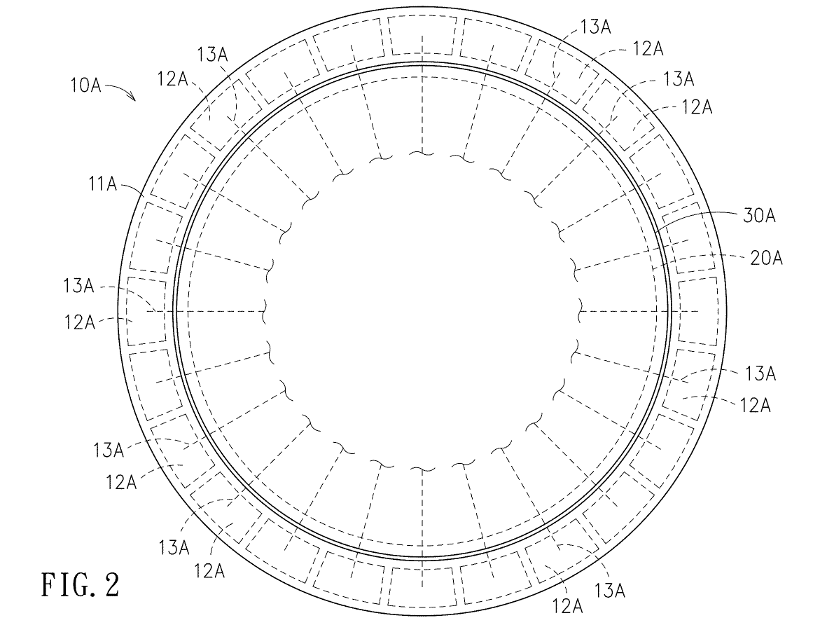

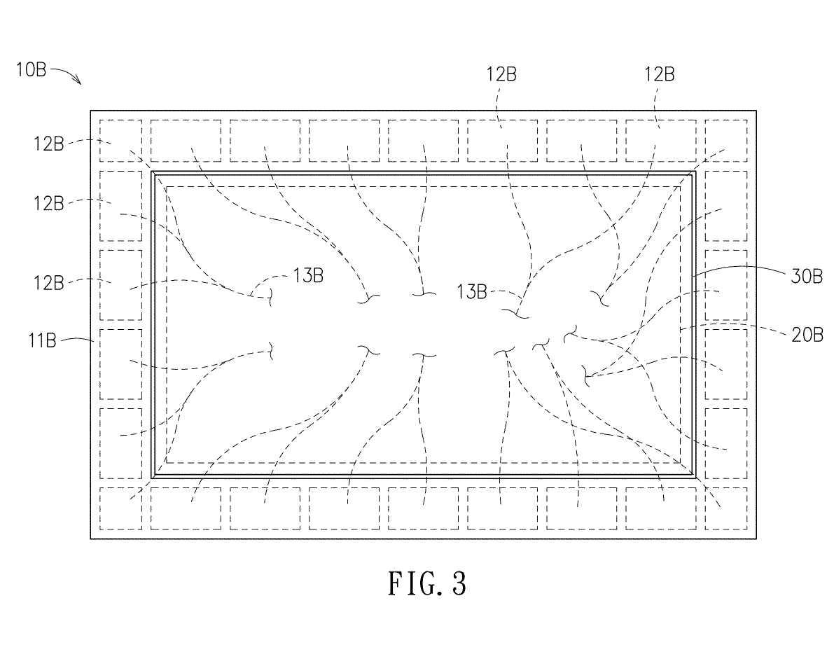

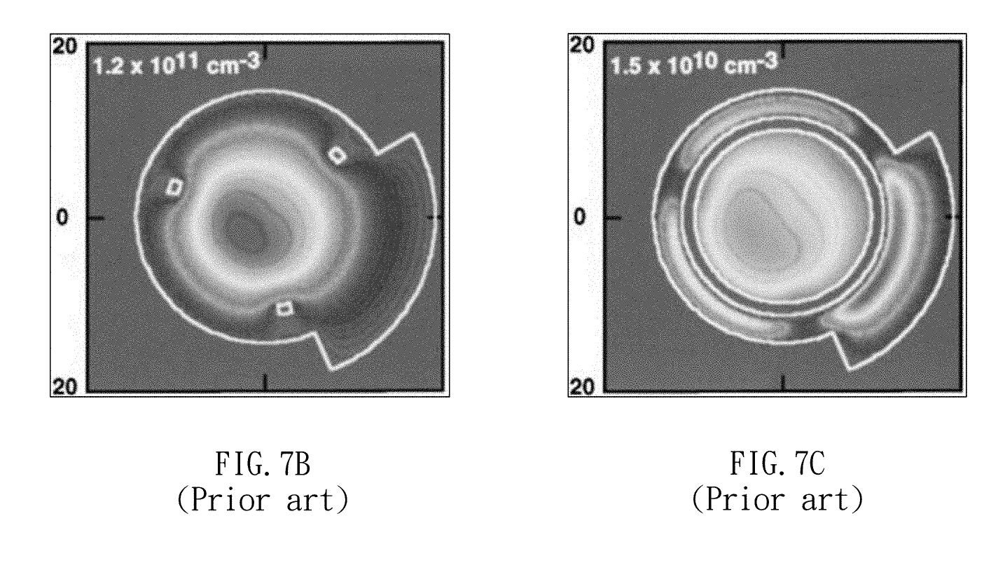

Referring now to FIG. 2 and FIG. 3, respective top views of FIG. 1 for two possible structuring of the focus ring 10 are shown. The main body 11A of the focus ring 10A of FIG. 2 is structured as a round frame, while the main body 11B of the focus ring 10B of FIG. 7C is structured as a rectangular frame. Generally speaking, in accordance with this disclosure, the shape or configuration of the main body of the focus ring is not limited to any specific or aforesaid shape. For example, in the focus ring 10A of FIG. 2, the main body 11A is to encircle the round base 20A, which is used to carry thereon a round workpiece 30A (a wafer for example) for machining, and thus the main body 11A is structured to be a round ring. On the other hand, in the focus ring 10B of FIG. 3, since the main body 11B is to encircle the rectangular base 20B, which is used to carry thereon a rectangular workpiece 30B (a substrate for example) for machining, and thus the main body 11B is structured to be a rectangular ring.

Referring back to FIG. 1, the plurality of electrodes 12 are made of metallic materials, and the neighboring electrodes 12 are spaced by a predetermined interval. The plurality of electrodes 12 are furnished inside the main body 11 by surrounding the base 20. In this disclosure, the shape, dimension and quantity of the electrode 12 is not limited, but per practical requirements. For example, the electrode 12 shown in FIG. 1 is formed by a thin sheet. In FIG. 2, since the main body 11A is a round frame structure, so the electrode 12A had a sector shape. In addition, in FIG. 3, since the main body 11B is a rectangular frame structure, so the electrode 12B had a rectangular shape. Nevertheless, in this disclosure, the shape of the electrode is not limited to the aforesaid description. For example, in FIG. 2, the electrode 12A can be shaped as a rectangle.

Each of the plurality of power cables 13 is connected electrically with a voltage source 14, a control unit 15 and at least one said electrode 12. In this embodiment as shown in FIG. 1, the power cable 13 enters the main body 11 from a bottom thereof and extends further to connect with the respective electrode 12 inside the main body 11. Thereupon, assembling and/or disassembling of the focus ring 10 would be much easier. The voltage source 14 can be a radio-frequency (RF) voltage source or a direct-current (DC) voltage source.

The voltage source 14 supplies individual voltage to each of the corresponding electrodes 12 via the respective power cables 13, and the supplies of individual voltages to respective electrodes 12 are controlled by the control unit 15. For example, referring to FIG. 2, in the case that each of the electrodes 12A is energized by an independent power cable 13A, then the plurality of electrodes 12A can be controlled have different voltages. On the other hand, referring to FIG. 3, in the case that a predetermined number (2, 3 or . . . ) of the electrodes 12B, neighbored to each or not, are energized by the same power cable 12B (even bifurcated to plural ends for each individual electrodes 12B), then it can be deemed to separate the plurality of electrodes 12B into plural subgroups of the electrodes 12B. Each the same subgroup of the electrodes 12B is energized by the same voltage, but different subgroups of electrodes 12B may receive different voltages. In this disclosure, the control of voltage supply is not limited to follow the aforesaid manner, but may be varied according to practical requirements.

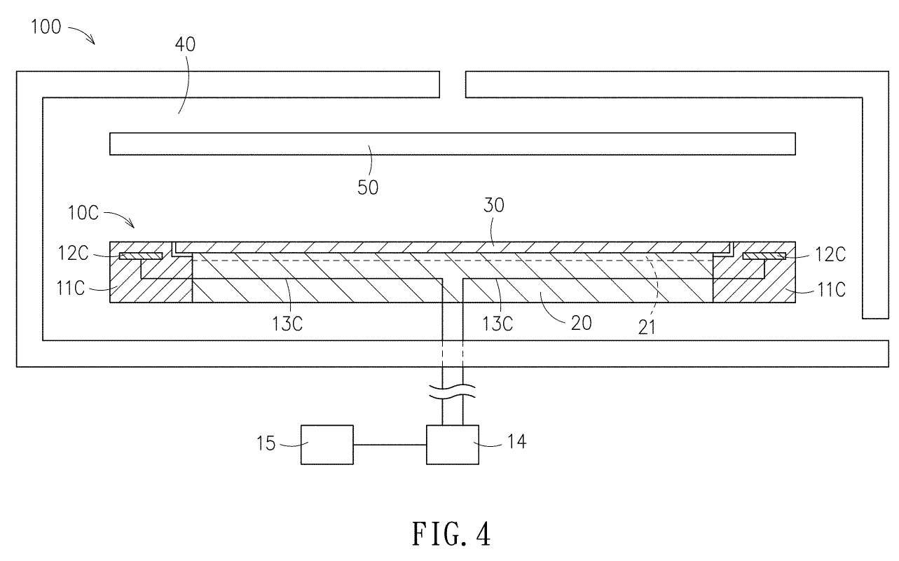

Referring now to FIG. 4, the plasma apparatus 100 of this disclosure may include a processing chamber 40 having thereinside a base 20 for supporting a workpiece 30. The base 20 may secure thereon a workpiece 30 by electrostatic adhesion. The workpiece 30 can be a wafer or a substrate. A lower electrode 21 connected electrically with an RF power source is located inside the base 20, while an upper electrode 50 is located inside the processing chamber 40 at a position above the base 20 so as to form an electrode pair with the lower electrode 21 in the base 20. In this disclosure, the plasma apparatus 100 is characterized in that a focus ring 10C is furnished to surround the base 20. The focus ring 10C includes a main body 11C, a plurality of electrodes 12C and a plurality of power cables 13C. The main body 11C, made of a dielectric material, is formed as a frame structure to surround the base 20. Each of the plurality of electrodes 12C is made of a metallic material, and the neighboring electrodes 12C are spaced by a predetermined interval. The plurality of electrodes 12C are furnished inside the main body 11 by surrounding the base 20. Each of power cables 13C is connected a voltage source 14, a control unit 15 and at least one electrode 12C. The voltage source 14 utilizes the corresponding power cable 13C to output a voltage to the respective electrode 12C. The control unit 15 is to control the voltages outputted to the corresponding electrodes 12C so as to allow each of the plurality of electrodes 12C to have an individual voltage.

In this embodiment, any foregoing focus ring 10, 10A or 10B of FIG. 1 to FIG. 3, respectively, can be the focus ring 10C here in FIG. 4.

In this embodiment, the power cable 13C enters the base 20 from a bottom thereof. After the power cable 13C enters the base 20, it extends further into the main body 11C so as finally to connect electrically a corresponding electrode 12C inside the main body 11C. Each of the plurality of power cables 13C forms a separable electric connection at the junction of the main body 11C and the base 20. Thereby, disassembling of the focus ring 10C from the base 20 can be performed more conveniently. It shall be explained that wiring of each said power cable is not limited to that shown in FIG. 1 or FIG. 4.

For the aforesaid plasma apparatus 100 of this disclosure has one said focus ring 10, thus the distribution of electric field inside the processing chamber 40 can be adjusted by varying the individual voltages outputted to the corresponding electrode 12, from which a different distribution of the voltage strengths would be presented to the surface of the focus ring 10.

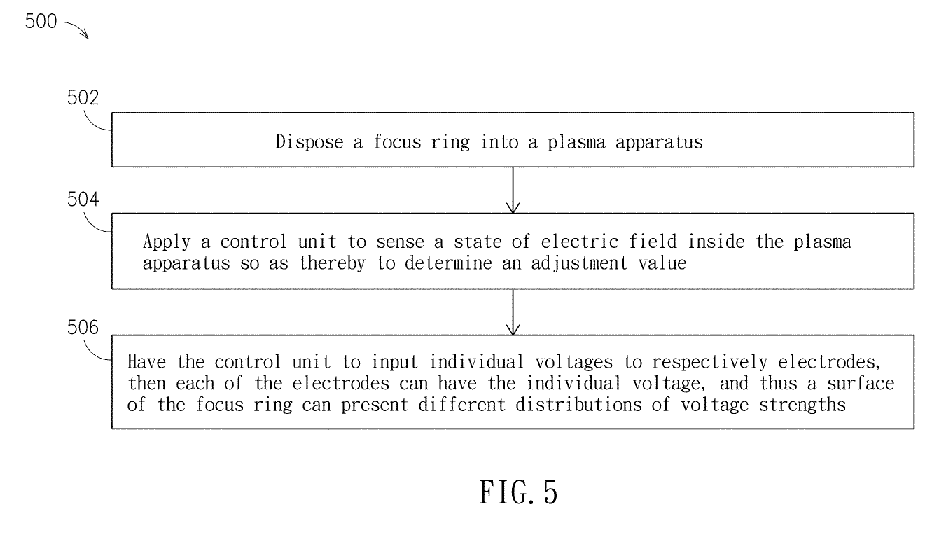

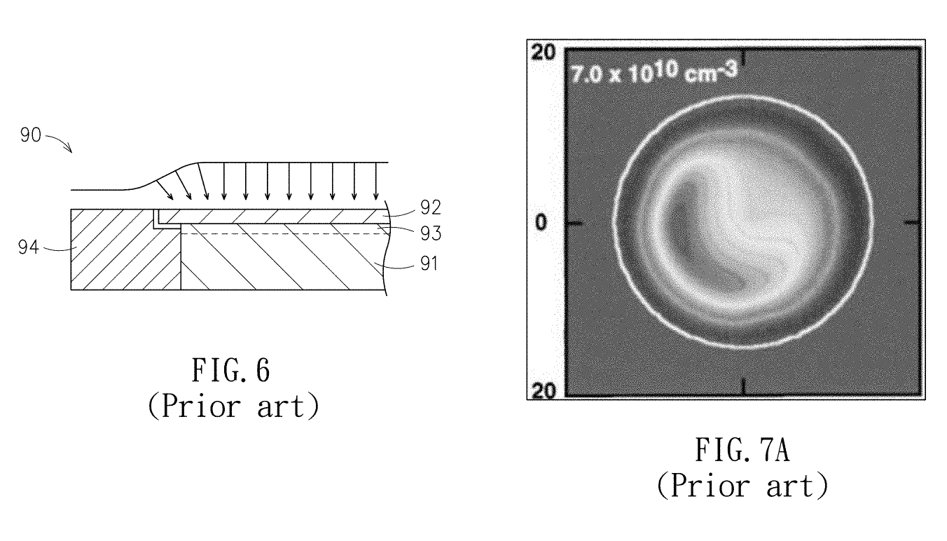

Referring now to FIG. 4 and FIG. 5, a flowchart 500 of a voltage-adjusting method using one focus ring of this disclosure includes the following steps:

Step 502: Dispose a focus ring 10 into a plasma apparatus 10;

Step 504: Apply a control unit 15 to sense a state of electric field inside the plasma apparatus 100, and then an adjustment value can be determined; and

Step 506: Have the control unit 15 to input individual voltages to a plurality of electrodes 12, respectively, such that the plurality of electrodes 12 can have a plurality of respective voltages. Thereupon, the surface of the focus ring 10 can present different distributions of the voltage strengths.

In summary, in the focus ring, the plasma apparatus using the focus ring and the voltage-adjusting method using the focus ring in accordance with the present disclosure, the focus ring has a main body made of a dielectric material, the main body is furnished thereinside a plurality of metal electrodes, and the plurality of electrodes are connected with a voltage source and a control unit via a plurality of respective power cables. By disposing the focus ring to surround the base carrying the workpiece inside the plasma apparatus, the distribution of plasma at the edge of the workpiece can then be varied by adjusting the individual voltages assigned to the respective electrodes.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A focus ring, comprising:
a main body, made of a dielectric material, formed as a frame structure to surround a base;
a plurality of electrodes, made of metallic materials, located inside the main body by surrounding the base, the neighboring ones of the plurality of electrodes being separated by an interval; and
a plurality of power cables, each of the plurality of power cables being connected electrically with a voltage source, a control unit and at least one of the plurality of electrodes, the voltage source inputting individual voltages to the plurality of electrodes via the plurality of respective power cables, the control unit controlling the plurality of electrodes to have correspondingly a plurality of voltages.

2. The focus ring of claim 1, wherein the main body is a round frame structure.

3. The focus ring of claim 1, wherein the main body is a rectangular frame structure.

4. The focus ring of claim 1, wherein the voltage source is one of an RF voltage source and a DC voltage source.

5. The focus ring of claim 1, wherein each of the plurality of power cables enters the main body from a bottom thereof and extends further to connect electrically with at least one of the plurality of electrodes inside the main body.

6. The focus ring of claim 1, wherein each of the plurality of power cables enters the base from a bottom thereof and extends further to enter the main body so as to connect electrically with at least one of the plurality of electrodes inside the main body.

7. The focus ring of claim 6, wherein a separable electric connection is formed to each of the plurality of power cables at a corresponding junction of the main body and the base.

8. A plasma apparatus, comprising:
a processing chamber;
a base, located inside the processing chamber, being to carry thereon a workpiece;
a lower electrode, located inside the base;
an upper electrode, located inside the processing chamber at a place above the base, forming an electrode pair with the lower electrode inside the base;
a focus ring, including:
a main body, made of a dielectric material, formed as a frame structure to surround the base;
a plurality of electrodes, made of metallic materials, located inside the main body by surrounding the base, the neighboring ones of the plurality of electrodes being separated by an interval; and
a plurality of power cables, each of the plurality of power cables being connected electrically with a voltage source, a control unit and at least one of the plurality of electrodes, the voltage source inputting individual voltages to the plurality of electrodes via the plurality of respective power cables, the control unit controlling the plurality of electrodes to have correspondingly a plurality of voltages.

9. A voltage-adjusting method, comprising the steps of:
disposing a focus ring into a plasma apparatus, the focus ring including a main body made of a dielectric material, a plurality of electrodes made of metallic materials and a plurality of power cables, the main body being formed as a frame structure to surround a base, the neighboring ones of the plurality of electrodes being separated by an interval, the plurality of electrodes being located inside the main body and surrounding the base, each of the power cables being connected with a voltage source, a control unit and at least one of the plurality of electrodes, the voltage source inputting individual voltages into the plurality of electrodes, respectively, correspondingly via the plurality of power cables;
applying the control unit to sense a state of electric field inside the plasma apparatus so as thereby to determine an adjustment value; and
having the control unit to control the individual voltages inputted respectively to the plurality of electrodes, so that the plurality of electrodes have a plurality of voltages respectively to allow a surface of the focus ring to present different distributions of voltage strengths.
